(19) United States
(12) Patent Application Publication
(10) Pub. No.: US 2002/0030260 A1
(43) Pub. Date: Mar. 14, 2002

(54) ELECTRONIC COMPONENT AND METHOD OF MANUFACTURE

(76) Inventor: LAWRENCE SCOTT KLINGBEIL JR., CHANDLER, AZ (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 09/033,099

(22) Filed: Mar. 2, 1998

(51) Int. Cl. H01L 21/44; H01L 21/48; H01L 21/50; H01L 23/495; H01L 23/06; H01L 23/52; H01L 23/48

(52) U.S. Cl. 257/684; 257/691; 257/692; 257/693; 438/123

(57) ABSTRACT

An electronic component includes a semiconductor substrate (101) with two surfaces (106, 108), a semiconductor device (102) at the first surface of the semiconductor substrate (101), and an electrically conductive layer at the second surface of the semiconductor substrate (101) wherein a first portion (123) of the electrically conductive layer is electrically coupled to the semiconductor device (102) and is located at a central portion and at corners of the second surface of the semiconductor substrate (101).

### BACKGROUND OF THE INVENTION

This invention relates, in general, to electronic components, and more particularly, to electrical interconnections of electronic components.

Many power transistors use wire bonds to electrically connect a source terminal from a transistor to a leadframe. However, a single wire bond produces high source inductance, which degrades the power, gain, and efficiency of the transistor. Multiple wire bonds between the source terminal and the leadframe can lower the source inductance, but multiple wire bonds also increase the cost and complexity of manufacturing the electronic components.

Other power transistors use a single source pad to cover the entire bottom surface of the semiconductor substrate wherein the source pad mounts directly onto a leadframe. The source pad has an interconnect path extending from and electrically coupled to the source terminal at the top surface of the semiconductor substrate. The source inductance of the source pads is lower than that of source wire bonds. The source pads also increase the heat dissipation efficiency of power transistors. However, wire bonds are still used to electrically couple the remaining gate and drain terminals, which suffer from the aforementioned wire bond problems.

Still other power transistors use flip chip bumps in place of wire bonds, but flip chip bumps do not have the heat dissipation efficiency of source pads because of thermal necking. Furthermore, flip chip bumps still use bonding pads or other areas of similar size, which increase the overall die size and, thus, the cost of power transistors.

Accordingly, a need exists for an electronic component that has low source inductance, high heat dissipation efficiency, and a small die size.

### BRIEF DESCRIPTION OF THE DRAWINGS

FIG. 1 illustrates an exploded isometric view of an embodiment of an electronic component in accordance with the present invention;

FIG. 2 illustrates an exploded isometric view of an alternative embodiment of the electronic component in accordance with the present invention; and

FIG. 3 illustrates an exploded isometric view of another alternative embodiment of the electronic component in accordance with the present invention.

For simplicity and clarity of illustration, elements in the drawings are not necessarily drawn to scale. Furthermore, the same reference numerals in different figures denote the same elements.

### DETAILED DESCRIPTION OF THE DRAWINGS

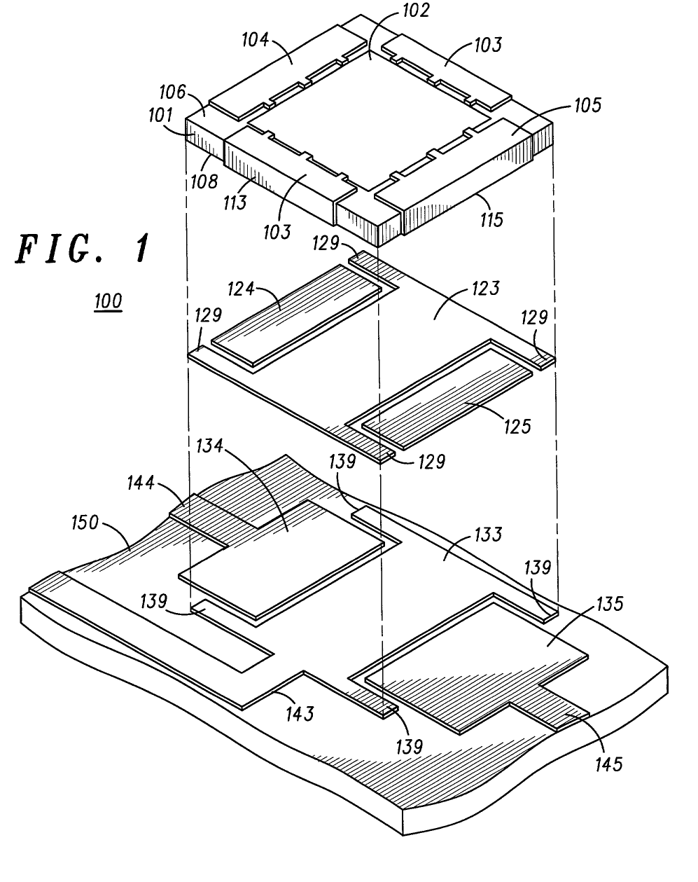

FIG. 1 illustrates an exploded isometric view of an electronic component 100. Component 100 includes, among other features, a substrate 101, a semiconductor device 102, an electrically conductive layer comprised of regions or portions 103, 104, and 105, another electrically conductive layer comprised of regions or portions 113, 115, 123, 124, 125, and 129, and a support substrate or circuit board 150 having electrically conductive traces, portions, or regions 133, 134, 135, 139, 143, 144, and 145.

Substrate 101 is the device substrate of component 100 and is preferably comprised of a semiconductor substrate such as gallium arsenide, silicon, or the like. The specific shape of substrate 101 is for illustration purposes only and is not intended to limit the scope of the subject invention. Substrate 101 has a top surface 106 and a bottom surface 108 opposite surface 106. Substrate 101 also has edge surfaces coupling surfaces 106 and 108 together. Surfaces 106 and 108 can each have two sets of opposite sides and can each have four corners at junctions of the opposite sides.

Semiconductor device 102 is formed in surface 106 of substrate 101. Because device 102 can have many different embodiments, the depicted block illustration of device 102 is only for the purpose of representing a semiconductor device. Device 102 can be a power transistor, an integrated amplifier, or the like. In the preferred embodiment, device 102 is a field effect transistor having gate, source, and drain electrodes. Device 102 also preferably has a channel or active area below the gate electrode and in a central portion of surface 106 of substrate 101. In an alternative embodiment, device 102 is a bipolar transistor having base, emitter, and collector electrodes.

An electrically conductive layer, comprised of regions or portions 103, 104, and 105, is disposed over surface 106 of substrate 101. As an example, the electrically conductive layer can be sputtered, evaporated, or plated onto substrate 101, and then the electrically conductive layer can be etched or otherwise patterned into physically separated portions 103, 104, and 105. In the preferred embodiment, portions 103, 104, and 105 are comprised of a metal such as copper, aluminum, tungsten, titanium, gold, or the like.

In the preferred embodiment, portions 103, 104, and 105 are electrically coupled to the source, gate, and drain electrodes, respectively, of device 102. In an alternative embodiment, portions 103, 104, and 105 are electrically coupled to the emitter, base, and collector electrodes, respectively, of device 102. As illustrated in FIG. 1, portion 103 of the electrically conductive layer is preferably split into two portions located at opposite sides of device 102 and at opposite sides of surface 106 of substrate 101. Portions 104 and 105 of the electrically conductive layer are also preferably located at opposite sides of device 102 and at opposite sides of surface 106.

Before substrate 101 is singulated from a larger substrate or wafer, substrate 101 is thinned, and then vias or holes are etched through substrate 101. The vias or holes are formed in the saw streets of the wafer. In other words, the vias or holes are formed at regions that will subsequently define the outer perimeter or boundary of substrate 101. The vias or holes are also located underneath portions 103, 104, and 105 and expose the backside or underside of portions 103, 104, and 105.

Subsequently, an electrically conductive layer is sputtered, evaporated, plated, or otherwise disposed over bottom surface 108 of substrate 101. The electrically conductive layer is also disposed onto the sidewalls of the previously formed vias or holes and onto the backside of portions 103, 104, and 105 located at the bottom of the vias or holes. This electrically conductive layer is then etched or otherwise patterned into regions or portions 113, 115, 123, 124, 125, and 129, and then substrate 101 is singulated from the larger substrate or wafer along the aforementioned saw streets. After the singulation process, portions 113 and 115 are located on and wrap-around the edge surfaces of substrate 101.

Portions 113, 115, 123, 124, 125, and 129 can be comprised of a metal similar to portions 103, 104, and 105. However, portions 113, 115, 123, 124, 125, and 129 are preferably comprised of a metal adhesion layer, a metal seed layer, and a plated solder layer. In the preferred embodiment, the solder used for portions 113, 115, 123, 124, 125, and 129 is comprised of any gold-based or lead-based solder that has a reflow temperature of less than approximately three hundred degrees Celsius, for reasons explained hereinafter.

Portion 113 is located along two opposite edge surfaces of substrate 101 and physically and electrically connects together portions 103 and 123. Portion 115 is located along a different edge surface of substrate 101 and electrically connects together portions 105 and 125. Another electrically conductive portion (not illustrated in FIG. 1) is located along yet another edge surface of substrate 101 that is hidden from view in FIG. 1. This other electrically conductive portion electrically connects together portions 104 and 124. As described earlier, the edge surfaces of substrate 101 physically couple top surface 106 to bottom surface 108. Therefore, in the preferred embodiment, portions 123, 124, and 125 are the source, gate, and drain contacts or terminals, respectively, for device 102.

In the preferred embodiment, portion 123 has an “H” or “I” shape such that portion 123 is absent from central regions of two opposite sides of surface 108. Portion 123 includes outer portions 129, which are located at the corners of surface 108 of substrate 101. Portion 123 is also located at a central portion of surface 108. Locating portion 123 at the center and the corners of surface 108 improves the mechanical, structural, and bonding properties of component 100, as explained hereinafter. Furthermore, by keeping portion 123 continuous and located at the central portion of surface 108 under at least all of the active area of device 102, the heat dissipation efficiency of component 100 is significantly improved when substrate 101 is thinned to less than approximately one hundred micrometers.

Portion 123 includes two recesses defined by portions 129 wherein the recesses are located at central regions of opposite sides of surface 108. Portions 124 and 125 are located in separate recesses and are located between different ones of portions 129. Portion 124 and some of portions 129 are located along a common side of surface 108 while portion 125 and different ones of portions 129 are located along a common side opposite that of portion 124. Portions 124 and 125 are physically separated from each other and are also physically separated from portion 123 to provide proper electrical operation of component 100. Portions 124 and 125 can be symmetric or asymmetric with each other. In an asymmetric embodiment, portion 125 is preferably larger than portion 124 because of the higher current carrying requirements of portion 125, which is coupled to the drain of device 102.

As illustrated in FIG. 1, portions 123, 124, and 125 serve as the bonding pads for substrate 101. By placing portions 123, 124, and 125 on bottom surface 108, substrate 101 is smaller than prior art substrates where the bonding pads are placed on the top surface of the semiconductor substrate. Therefore, with the smaller size of substrate 101, a larger number of substrates can be singulated from a single wafer, which reduces the cost of component 100.

Circuit board 150 is electrically insulative but has electrically conductive traces or regions 133, 134, 135, 139, 143, 144, and 145. Regions 133, 134, 135, 139, 143, 144, and 145 can be comprised of metals such as silver, gold, copper, and the like. Regions 133, 134, 135, and 139 are preferably symmetric or at least similar in size and shape to portions 123, 124, 125, and 129, respectively. Regions 143, 144, and 145 electrically couple regions 133, 134, and 135, respectively, to other electronic devices (not illustrated in FIG. 1) also mounted to board 150.

When regions 133, 134, 135, and 139 are symmetrical to portions 123, 124, 125, and 129, respectively, lower parasitic source, gate, and drain inductances and resistances are achieved. This results in improved electrical performance for component 100. In this preferred embodiment, board 150 is suitable for use as a direct-chip-attach substrate wherein portions 123, 124, 125, and 129 of substrate 101 are directly attached or connected to regions 133, 134, 135, and 139, respectively, of board 150. No separate leadframe is needed between substrate 101 and board 150.

Preferably, either portions 123, 124, 125, and 129 are comprised of plated solder or regions 133, 134, 135, and 139 are comprised of plated solder. By eliminating additional solder paste and solder preforms from component 100, solder bleeding problems are more easily eliminated during the assembly of substrate 101 and board 150. This elimination of additional solder paste and preforms also reduces the chance of forming voids between substrate 101 and board 150, and the reduction in void formation improves the heat dissipation, the reliability, and the electrical performance of component 100 because of the larger contact area with board 150. Furthermore, by preferably keeping the reflow temperature of the plated solder at a temperature below approximately three hundred degrees Celsius, the assembly process will not adversely affect device 102 or portions 103, 104, and 105, especially when device 102 or portions 103, 104, and 105 are comprised of aluminum. Moreover, by preferably having portion 123 at the geometric center and at the corners of surface 108 of substrate 101, the mechanical, structural, and bonding characteristics between substrate 101 and board 150 are improved.

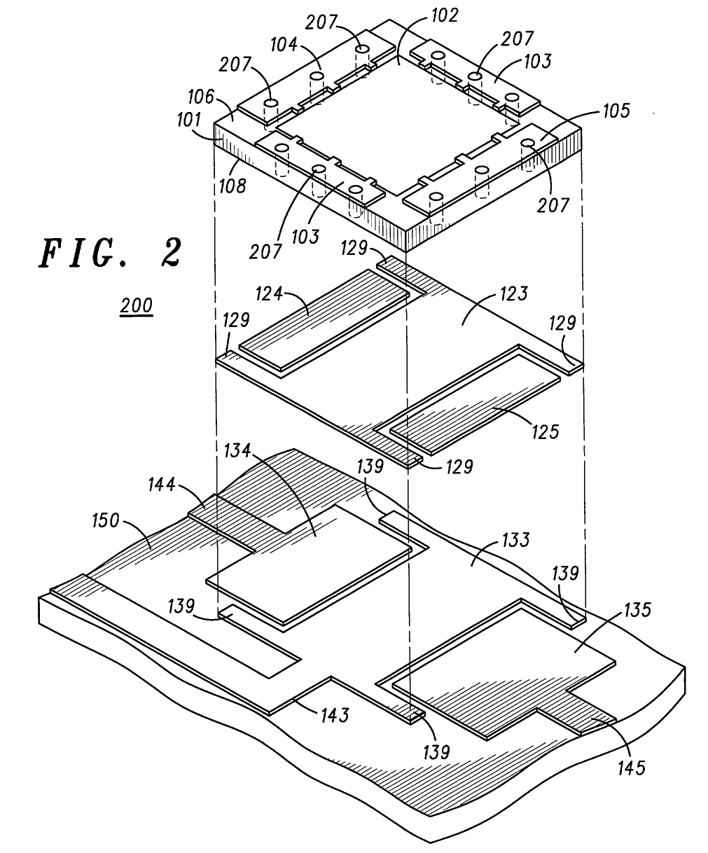

FIG. 2 illustrates an exploded isometric view of an electronic component 200, which is an alternative embodiment of component 100 in FIG. 1. Component 200 is similar to component 100, but component 200 has through-holes or vias 207 extending through substrate 101 from surface 106 to surface 108. Vias 207 can be located outside a periphery of device 102 and at a perimeter of substrate 101. Alternatively, vias 207 can be located at a central portion of substrate 101. Vias 207 can be either coated or filled with an electrically conductive material to form electrically conductive vias. One set of vias 207 electrically couple together portions 103 and 123; a different set of vias 207 electrically couple together portions 104 and 124; and yet another set of vias 207 electrically couple together portions 105 and 125.

In the preferred embodiment of component 200, vias 207 of component 200 replace portions 113 and 115 and other similar edge surface or wrap-around portions of component 100. However, in an alternative embodiment of component 200, vias 207 can be used in addition to portions 113 and 115 and the other similar edge surface or wrap-around portions.

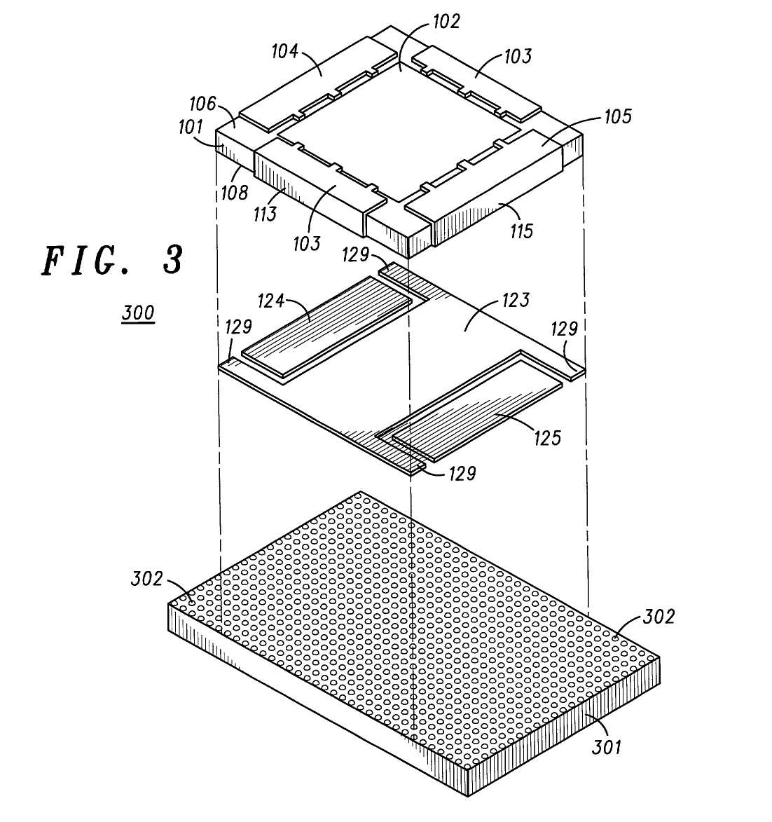

FIG. 3 illustrates an exploded isometric view of an electronic component 300, which is an alternative embodiment to component 100 of FIG. 1. Component 300 includes a ball grid array (BGA) substrate 301 with a ball grid array 302. Array 302 is electrically coupled to portions 123, 124, 125, and 129 on surface 108 of substrate 101. BGA substrate 301 of component 300 is substituted for circuit board 150 of component 100 in FIG. 1. BGA substrate 301 can also be substituted for circuit board 150 of component 200 in FIG. 2.

Therefore, an improved electronic component is provided to overcome the disadvantages of the prior art. The electronic component described herein has low lead inductance, high heat dissipation efficiency, and a small die size.

While the invention has been particularly shown and described mainly with reference to preferred embodiments, it will be understood by those skilled in the art that changes in form and detail may be made without departing from the spirit and scope of the invention. For instance, the numerous details set forth herein such as, for example, the specific material compositions and the specific “H” or “I” configuration of portion 123 in FIGS. 1, 2, and 3 are merely provided to facilitate the understanding of the present invention and are not provided to limit the scope of the invention. As an example, the edges of portions 123 and 124 that are adjacent to each other can have a curved shape similar to a semicircle extending from one corner to an adjacent corner of surface 108. The adjacent edges of portions 123 and 125 can also have a similar curved perimeter. In another alternative embodiment, portions 124 and 125 can be located along the same side of surface 108. In this embodiment, portion 123 is located along three sides of surface 108 to improve heat dissipation from device 102, and portion 123 can have a single recess in which both portions 123 and 125 are located. Alternatively, portion 123 can have two separate recesses along the same side of surface 108.

Accordingly, the disclosure of the present invention is not intended to be limiting. Instead, the disclosure of the present invention is intended to be merely illustrative of the scope of the invention, which is set forth in the following claims.

1. An electronic component comprising:
a substrate having first and second surfaces opposite each other; and
a first electrically conductive layer at the second surface wherein the first electrically conductive layer has an “H” shape.

2. The electronic component of claim 1 wherein the first electrically conductive layer is electrically coupled to a transistor at the first surface of the substrate.

3. The electronic component of claim 1 wherein the first electrically conductive layer is electrically coupled to the first surface of the substrate by electrically conductive vias extending through the substrate.

4. The electronic component of claim 1 wherein the first electrically conductive layer is electrically coupled to the first surface of the substrate by electrically conductive regions at edge surfaces of the substrate, the edge surfaces coupling the first and second surfaces of the substrate together.

5. The electronic component of claim 1 wherein the first electrically conductive layer is comprised of solder.

6. The electronic component of claim 5 wherein the solder has a reflow temperature of less than three hundred degrees Celsius.

7. The electronic component of claim 1 further comprising a ball grid array directly connected to the first electrically conductive layer at the second surface of the substrate.

8. The electronic component of claim 1 further comprising an electrically insulative substrate having an electrically conductive region directly connected to the first electrically conductive layer at the second surface of the substrate wherein the electrically conductive region has an “H” shape similar to the “H” shape of the first electrically conductive layer.

9. An electronic component comprising:
a semiconductor substrate having a first surface and a second surface opposite the first surface;
a transistor at the first surface and having first, second, and third electrodes; and
an electrically conductive layer at the second surface, a first portion of the electrically conductive layer electrically coupled to the first electrode, located at a central portion of the second surface, and located at corners of the second surface.

10. The electronic component of claim 9 wherein the electrically conductive layer is solder and wherein the first portion of the electrically conductive layer is-continuous and is absent from central regions of two opposite sides of the second surface.

11. The electronic component of claim 9 wherein the first portion of the electrically conductive layer has a curved perimeter from a corner of the second surface to an adjacent corner of the second surface.

12. The electronic component of claim 9 wherein the transistor is a bipolar transistor and wherein the first electrode is an emitter electrode.

13. The electronic component of claim 9 further comprising a second portion of the electrically conductive layer at the second surface wherein the second portion is separated from the first portion of the electrically conductive layer and wherein the second portion of the electrically conductive layer is electrically coupled to the second electrode.

14. The electronic component of claim 13 wherein the first and second portions of the electrically conductive layer are located along a common side of the second surface and wherein the second portion along the common side is located between different regions of the first portion along the common side.

15. An electronic component comprising:
a semiconductor substrate having top and bottom surfaces opposite each other and edge surfaces coupling the top and bottom surfaces together, the top and bottom surfaces each having first and second sides opposite each other and third and fourth sides opposite each other, the top and bottom surfaces each having corners at junctions of their respective first, second, third, and fourth sides;
a transistor having an active area in a central portion of the top surface, the transistor having gate, source, and drain electrodes;
a metal layer supported by the top surface, a first portion of the metal layer at the first side of the top surface and electrically coupled to the gate electrode, a second portion of the metal layer at the second side of the top surface and electrically coupled to the drain electrode, a third portion of the metal layer at the third side of the top surface and electrically coupled to the source electrode, and a fourth portion of the metal layer at the fourth side of the top surface and electrically coupled to the source electrode, the first, second, and third portions of the metal layer physically separated from each other, and the first, second, and fourth portions of the metal layer physically separated from each other; and
a solder layer adjacent to the bottom surface, a first portion of the solder layer at the first side of the bottom surface and electrically coupled to the first portion of the metal layer, a second portion of the solder layer at the second side of the bottom surface and electrically coupled to the second portion of the metal layer, a third portion of the solder layer at the third side, the fourth side, the corners, and a central portion of the bottom surface and electrically coupled to the third and fourth portions of the metal layer, and the first, second, and third portions of the solder layer physically separated from each other.

16. The electronic component of claim 15 wherein the first portions of the metal and solder layers are electrically coupled together by a first set of electrically conductive vias through the semiconductor substrate, wherein the second portions of the metal and solder layers are electrically coupled together by a second set of electrically conductive vias through the semiconductor substrate, wherein the third portions of the metal and solder layers are electrically coupled together by a third set of electrically conductive vias through the semiconductor substrate, wherein the fourth portion of the metal layer and the third portion of the solder layer are electrically coupled together by a fourth set of electrically conductive vias through the semiconductor substrate, and wherein the first, second, third, and fourth set of electrically conductive vias are located at a periphery of the semiconductor substrate and at a periphery of the transistor.

17. The electronic component of claim 15 wherein the first portions of the metal and solder layers are electrically coupled together by a first electrically conductive region at a first one of the edge surfaces, wherein the second portions of the metal and solder layers are electrically coupled together by a second electrically conductive region at a second one of the edge surfaces, wherein the third portions of the metal and solder layers are electrically coupled together by a third electrically conductive region at a third one of the edge surfaces, and wherein the third portion of the solder layer and the fourth portion of the metal layer are electrically coupled together by a fourth electrically conductive region at a fourth one of the edge surfaces.

18. The electronic component of claim 15 wherein the third portion of the solder layer is located at all of the corners of the bottom surface and under all of the active area of the transistor, wherein the third portion of the solder layer has an “H” shape, and wherein the solder layer has a reflow temperature of less than approximately three hundred degrees Celsius.

19. The electronic component of claim 18 further comprising a ball grid array coupled to the solder layer at the bottom surface of the semiconductor substrate.

20. The electronic component of claim 18 further comprising an electrically insulative circuit board having electrically conductive traces directly attached to the solder layer at the bottom surface of the semiconductor substrate wherein the electrically conductive traces have a similar shape and size as the solder layer.

21. A method of manufacturing an electronic component comprising:
providing a semiconductor substrate having top and bottom surfaces opposite each other and edge surfaces coupling the top and bottom surfaces together, the top and bottom surfaces each having first and second sides opposite each other and third and fourth sides opposite each other, the top and bottom surfaces each having corners at junctions of their respective first, second, third, and fourth sides;
forming a transistor having an active area in a central portion of the top surface, the transistor having gate, source, and drain electrodes;
disposing a metal layer on the top surface, a first portion of the metal layer at the first side of the top surface and electrically coupled to the gate electrode, a second portion of the metal layer at the second side of the top surface and electrically coupled to the drain electrode, a third portion of the metal layer at the third side of the top surface and electrically coupled to the source electrode, and a fourth portion of the metal layer at the fourth side of the top surface and electrically coupled to the source electrode, the first, second, and third portions of the metal layer physically separated from each other, the first, second, and fourth portions of the metal layer physically separated from each other; and
disposing a solder layer adjacent to the bottom surface, a first portion of the solder layer at the first side of the bottom surface and electrically coupled to the first portion of the metal layer, a second portion of the solder layer at the second side of the bottom surface and electrically coupled to the second portion of the metal layer, a third portion of the solder layer at the third side, the fourth side, the corners, and a central portion of the bottom surface and electrically coupled to the third and fourth portions of the metal layer, and the first, second, and third portions of the solder layer physically separated from each other.
